(19) United States
(12) Patent Application Publication
(10) Pub. No.: US 2010/0079149 A1
(43) Pub. Date: Apr. 1, 2010

(54) CIRCUIT TESTING APPARATUS AND SYSTEM

(75) Inventors: Syuji Takada, Kawasaki (JP); Yoshinori Mesaki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/570,885

(22) Filed: Sep. 30, 2009

(30) Foreign Application Priority Data
Oct. 1, 2008 (JP) 2008-256449

(51) Int. Cl. G01R 31/02

(52) U.S. Cl. 324/537

(57) ABSTRACT

A circuit testing apparatus testing interconnectivity between two integrated circuits including: a data writing unit writing test pattern data for causing the outputting one of the two integrated circuits to perform a predetermined operation into a data buffer of the inputting integrated circuit; and a test control signal generating unit generating a test control signal for causing the inputting integrated circuit to read the test pattern data from the data buffer and provide the test pattern data to the outputting integrated circuit.

### CROSS-REFERENCE TO RELATED APPLICATION

This application is based upon and claims the benefit of priority from the prior Japanese Patent Application No. 2008-256449 filed on Oct. 1, 2008, the entire contents of which are incorporated herein by reference.

### BACKGROUND

1. Field

The embodiments discussed herein are related to a circuit testing apparatus and a circuit testing system for verifying interconnectivity between circuits.

2. Description of Related Art

As the semiconductor integrated circuit technology such as LSI (Large-Scale Integration) progresses, gate and external pin counts are increasing. With this increase, the complexity of logic design and verification is increasing and test patterns used in testing such as evaluations, system tests, or debugging are also increasing in number and complexity, contributing to lengthening the development time of multifunctional LSIs such as system LSIs. For example, Japanese Laid-Open Patent Publication No. 5-66245 discloses an apparatus for testing highly-functional printed circuit boards containing multiple integrated circuits.

Especially in Very-Large-Scale Integration Circuits using more than one hundred million transistors, a large number of associated circuits such as memories are also contained and the development of their drivers and applications software is not straightforward. Accordingly, establishing an evaluation environment for such VLSIs requires a huge number of man-hours and enormous cost. One example LSI evaluation is BIST (Built-In Self Test). However, BIST can test only a particular LSI itself but cannot evaluate interconnectivity with another LSI connected to it.

One connectivity testing method commonly used at present is JTAG (Joint Test Action Group) testing. However, the JTAG testing has problems that it cannot verify the actual speed of high-speed signals, can verify only electrical connectivity but not the interconnectivity including logical connectivity. Furthermore, main-signal interfaces are shifting from parallel to serial transmission and interfaces with transmission rates higher than 5 gigabytes are emerging, which necessitates verification of interconnectivity using actual devices.

Designing a prototype circuit board for interconnectivity verification requires a huge number of man-hours and enormous cost as stated above. It may require eventually as many man-hours as the actual device design. Therefore, verification of interconnectivity is often performed by referring to specifications for each integrated circuit, such as data sheets, and/or by performing simulations and evaluation itself is performed on an actual system.

However, it is difficult at present to faithfully simulate analog behavior. Behavior in a simulation differs from that of an actual device. That is, even if a simulation shows that connection can be established, an actual verification on an actual device often shows that the connection cannot in fact be established. If an interconnection problem arises after a system has been actually fabricated, a major redesign needs to be done.

### SUMMARY

According to an embodiment, a circuit testing apparatus testing interconnectivity between two integrated circuits including: a data writing unit writing test pattern data for causing the outputting one of the two integrated circuits to perform a predetermined operation into a data buffer of the inputting integrated circuit; and a test control signal generating unit generating a test control signal for causing the inputting integrated circuit to read the test pattern data from the data buffer and provide the test pattern data to the outputting integrated circuit.

It is to be understood that both the foregoing summary description and the following detailed description are explanatory as to some embodiments of the present invention, and not restrictive of the present invention as claimed.

### BRIEF DESCRIPTION OF THE DRAWINGS

FIG. 1 illustrates a configuration of a circuit testing system according to a first example embodiment;

FIG. 2 illustrates the configuration of the circuit testing system illustrated in FIG. 1 in greater detail;

FIG. 3 illustrates a configuration of a circuit testing system according to a second example embodiment;

FIG. 4 illustrates a configuration of a circuit testing apparatus according to the second example embodiment; and

FIG. 5 illustrates a configuration of a circuit testing system according to a third example embodiment.

### DESCRIPTION OF EXAMPLE EMBODIMENTS

### First Example Embodiment

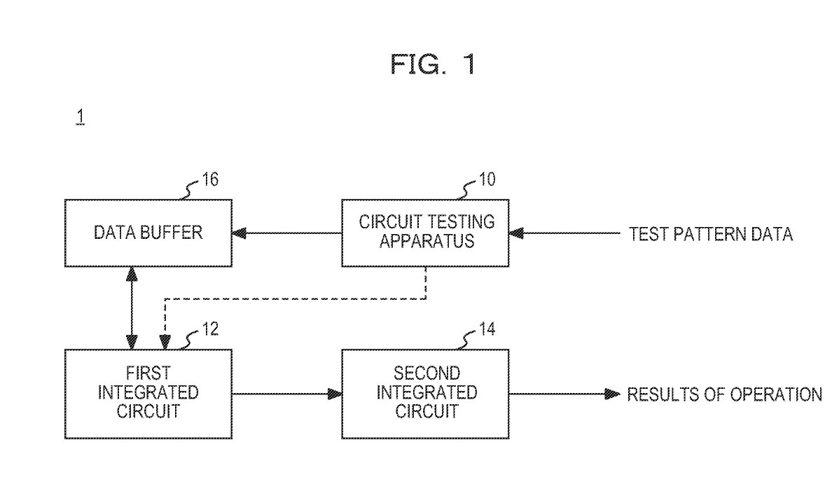

FIG. 1 illustrates a configuration of a circuit testing system according to a first example embodiment.

The circuit testing system 1 in FIG. 1 includes a circuit testing apparatus 10, a first integrated circuit 12, a second integrated circuit 14, and an external data buffer 16 of the first integrated circuit 12. The first and second integrated circuits 12 and 14 may implement the same function or different functions.

Test pattern data used for testing the second integrated circuit 14 is input from an information processor such as a personal computer (PC) or a simple signal generator to the circuit testing apparatus 10. The apparatus that generates the test pattern data may be configured to generate a basic fixed pattern or to generate an arbitrary data pattern by using an FPGA (Field Programmable Gate Array). Alternatively, the test pattern generating apparatus may be configured to dump a buffer pattern from simulation data obtained by a simulation such as an RTL (Register Transfer Level) simulation and input the result to the circuit testing apparatus 10. The circuit testing apparatus 10 writes the input test pattern data into the data buffer 16. The circuit testing apparatus 10 generates a test control signal that activates data output peripheral circuits contained in the first integrated circuit 12.

In response to the test control signal provided from the circuit testing apparatus 10, the first integrated circuit 12 reads test pattern data from the data buffer 16 and outputs the test pattern data to the second integrated circuit 14. The second integrated circuit 14 operates according to the test pattern data and the result of the operation is monitored by an information processor such as a personal computer (PC).

In this way, by checking the result of operation of the second integrated circuit 14 operating according to a signal provided from the first integrated circuit 12 which acts as a signal generator, the interconnectivity between the first and second integrated circuits 12 and 14 can be verified. If the second integrated circuit 14 does not output expected data, it can be determined that there is a defect in the connection between the first and second integrated circuits 12 and 14.

While the data buffer 16 is provided externally to the first integrated circuit 12 in the present example embodiment, the data buffer 16 may be an internal memory of the first integrated circuit 12. In that case, a memory interface needs to be provided externally to the first integrated circuit 12 so that data can be written in the internal memory in the first integrated circuit 12 during a test.

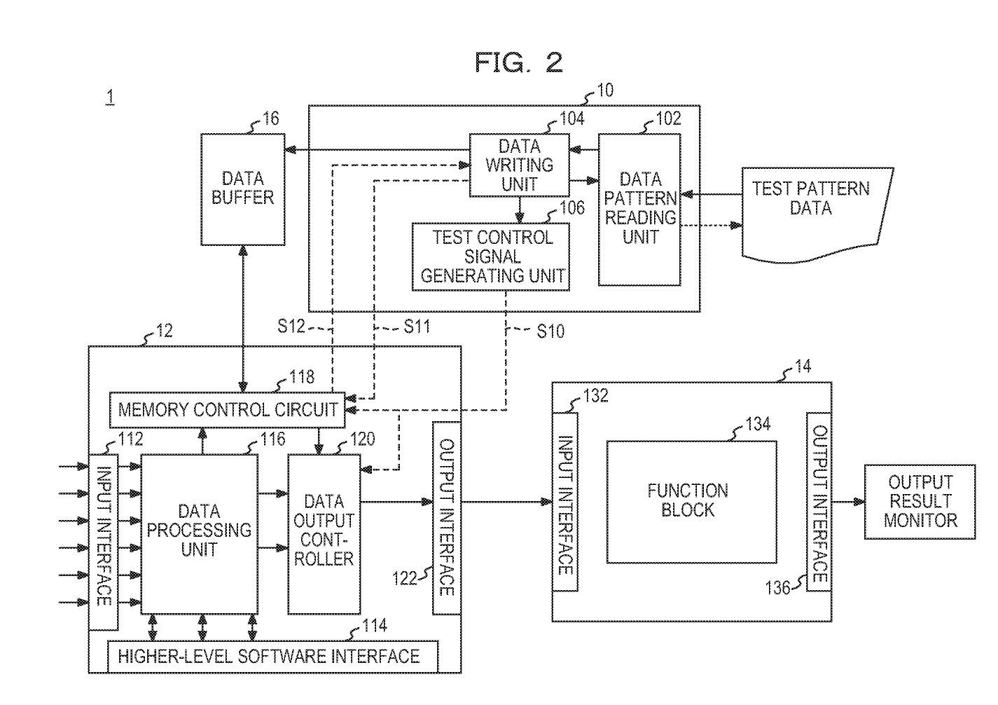

FIG. 2 illustrates the configuration of the circuit testing system 1 illustrated in FIG. 1 in greater detail. The solid arrows in FIG. 2 represent data flows and the dashed arrows represent control signal flows.

The circuit testing apparatus 10 includes a data pattern reading unit 102, a data writing unit 104, and a test control signal generating unit 106. The data pattern reading unit 102 is capable of reading test pattern data from an information processor or a signal generator. In particular, the data pattern reading unit 102 sends a request to an information processor or a signal generator, which, in response to the request, returns test pattern data to the data pattern reading unit 102. The data writing unit 104 is capable of writing the read test pattern data into the data buffer 16. The data writing unit 104 is also capable of sending a read instruction signal S11 to the first integrated circuit 12 to instruct the first integrated circuit 12 to read data from the data buffer 16 and receiving a read completion signal S12 indicating the completion of reading the data from the first integrated circuit 12. The test control signal generating unit 106 is capable of generating a test control signal S10 that causes a data output peripheral circuit of the first integrated circuit 12 to read test pattern data from the data buffer 16 and to provide the test pattern data to the second integrated circuit 14. The test control signal generating unit 106 is capable of generating the test control signal S10 and inputting it in the first integrated circuit 12 in response to an enable signal from the data writing unit 104.

The first integrated circuit 12 includes an input interface 112, a higher-level software interface 114, a data processing unit 116, a memory control circuit 118, a data output controller 120, and an output interface 122. The input interface 112 is an interface for receiving data stored in a memory such as a RAM (Random Access Memory) or a ROM (Read Only Memory) contained in a device in which the first integrated circuit 12 is actually integrated. The higher-level software interface 114 is an interface for sending and receiving data and/or programs to and from higher-level software. The data processing unit 116 is a processing unit that processes data input through the input interface 112. The memory control circuit 118 is capable of writing data processed by the data processing unit 116 into data buffer 16 and also reading data stored in the data buffer 16. The data output controller 120 is capable of outputting data processed by the data processing unit 116 or data read by the memory control circuit 118 from the data buffer 16. The output interface 122 is an interface for outputting data to the outside of the first integrated circuit 12.

The second integrated circuit 14 includes an input interface 132, a function block 134, and an output interface 136. The input interface 132 is connected to the output interface 122 of the first integrated circuit 12 for receiving data output from the first integrated circuit 12. The function block 134 is a circuit block operating to implement a predetermined function according to data input through the input interface 132. The output interface 136 is an interface for outputting data to the outside of the second integrated circuit 14 and, in the present example embodiment, is connected to an information processor such as a personal computer (PC).

In a test, first the data pattern reading unit 102 of the circuit testing apparatus 10 reads test pattern data for testing the second integrated circuit 14 from the information processor or signal generator. The data writing unit 104 of the circuit testing apparatus 10 writes the read test pattern data into the data buffer 16.

The test control signal generating unit 106 of the circuit testing apparatus 10 generates a test control signal S10 and sends the test control signal S10 to the data output peripheral circuits of the first integrated circuit 12, namely the memory control circuit 118 and the data output controller 120. In response to the signal S10, the memory control circuit 118 and the data output controller 120 become active.

Then the data writing unit 104 of the circuit testing apparatus 10 sends a read instruction signal S11 instructing to read data stored in the data buffer 16 to the memory control circuit 118 of the first integrated circuit 12. In response to the signal S11, the memory control circuit 118 reads test pattern data from the data buffer 16. Upon completion of the reading the data, the memory control circuit 118 sends a read completion signal S12 indicating the completion of the data reading to the data writing unit 104 of the circuit testing apparatus 10.

The data output controller 120 outputs the test pattern data read by the memory control circuit 118 to the second integrated circuit 14 through the output interface 122. The second integrated circuit 14 operates to implement a predetermined function according to the test pattern data. Data resulting from the operation of the second integrated circuit 14 is output through the output interface 136. If the data matches the data expected to be output when the predetermined function is implemented by the second integrated circuit 14, it is determined that the connection between the first and second integrated circuits 12 and 14 is properly established. On the other hand, if the data does not match the expected data, it is determined that there is a defect in the connection between the first and second integrated circuits 12 and 14.

The memory control circuit 118, the data output controller 120, and the output interface 122 of the first integrated circuit 12 function as described above to enable the first integrated circuit 12 to cooperate with the circuit testing apparatus 10 to act as a signal generator which generates a test signal for testing the second integrated circuit 14. Accordingly, the interconnectivity between the first and second integrated circuits 12 and 14 can be evaluated without necessarily having to cause the data processing unit 116 of the first integrated circuit 12, which functions and operates in a complex manner, to operate.

The circuit testing system according to the present example embodiment can facilitate evaluation and verification of the waveform characteristics of a high-speed interface by using actual devices (integrated circuits). Interface between LSIs is becoming increasingly faster and the necessity to treat digital signals as analog signals has arisen. Such high-speed interfaces often fail to establish connection in practice due to noise or crosstalk even if the connectivity has been verified on a specification basis. Therefore, circuit testing system according to the present example embodiment is advantageous in evaluation and verification of wave characteristics of high-speed interfaces.

### Second Example Embodiment

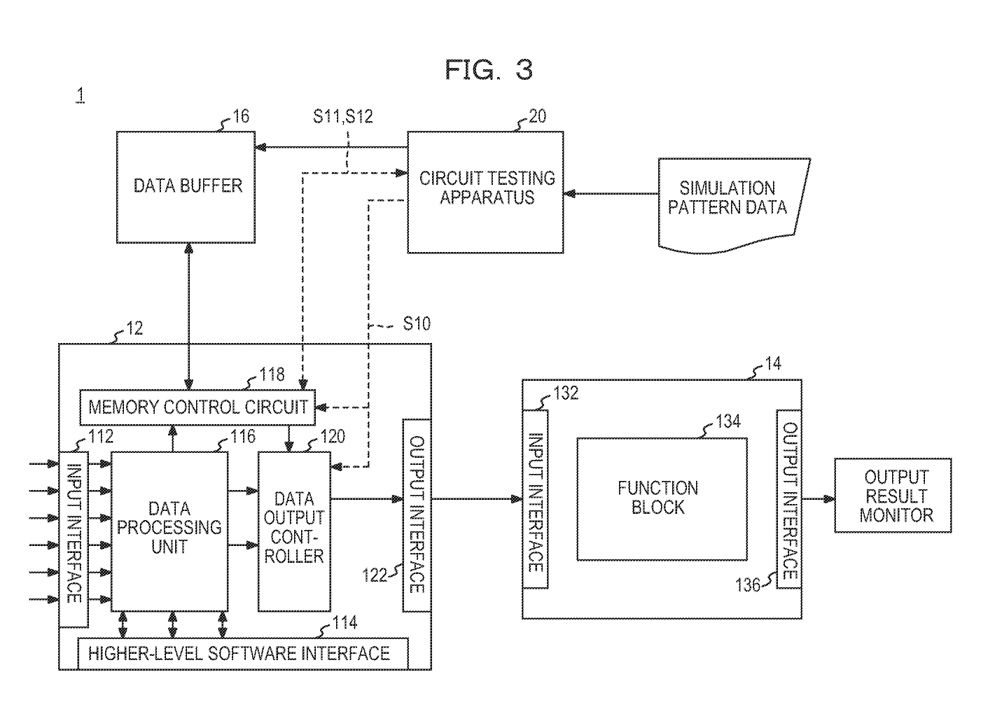

With the miniaturization of LSIs, the development costs of the LSIs have increased in these years and the manufacturing costs of masks and the like have become very expensive. Against this backdrop, an approach is going mainstream in which a functional verification model (emulation/prototyping circuit) is developed first by using an FPGA or the like and then an actual LSI is developed, with the aims of reducing the remake rate of LSIs and speeding up functional verification of the LSIs. FIG. 3 illustrates a second example embodiment, which is a circuit testing system in which a functional verification model is introduced in a circuit testing apparatus.

The circuit testing system 2 in FIG. 3 has the same configuration as the circuit testing system according to the first example embodiment illustrated in FIG. 2, except that a functional verification model is introduced in a circuit testing apparatus 20. Therefore the description of the components of the circuit testing system 2 that are the same as those in the first example embodiment will be omitted in the following description.

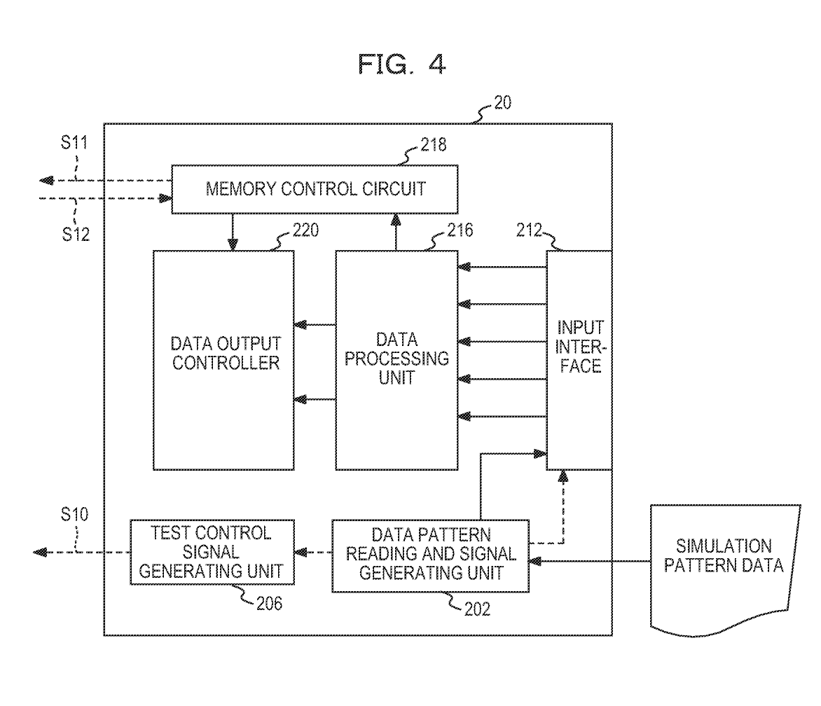

A functional verification model is introduced in the circuit testing apparatus 20. In particular, the circuit testing apparatus 20 includes as a data writing unit a so-called emulation circuit that imitates the functionality of a first integrated circuit 12. FIG. 4 illustrates a configuration of the circuit testing apparatus 20 according to the second example embodiment.

The circuit testing apparatus 20 in FIG. 4 includes a data pattern reading and signal generating unit 202, a test control signal generating unit 206, an input interface 212, a data processing unit 216, a memory control circuit 218, and a data output controller 220.

The data pattern reading and signal generating unit 202 is capable of reading simulation pattern data from an information processor or a signal generator. In particular, the data pattern reading and signal generating unit 202 sends a request to an information processor or a signal generator, which then returns test pattern data to the data pattern reading and signal generating unit 202 in response to the request. The data pattern reading and signal generating unit 202 provides the read simulation pattern data to the input interface 212 and at the same time issues a send data instruction to the input interface 212 to cause the input interface 212 to send out the data. The simulation pattern data here is data used by the circuit testing apparatus 20 to verify functions of the first integrated circuit 12 by simulation. In the second example embodiment, data resulting from internal processing by the circuit testing apparatus 20 is the test pattern data for testing a second integrated circuit 14.

The data pattern reading and signal generating unit 202 is also capable of generating an enable signal that enables the test control signal generating unit 206 to generate a test control signal. The test control signal generating unit 206 is capable of generating a test control signal S10 that causes a data output peripheral circuit of the first integrated circuit 12 to read test pattern data from a data buffer 16 and provide the test pattern data to the second integrated circuit 14.

The input interface 212 sends simulation pattern data provided from the data pattern reading and signal generating unit 202 to the data processing unit 216 in response to an instruction from the data pattern reading and signal generating unit 202. The data processing unit 216 is a processing unit that processes data input through the input interface 212. In particular, the data processing unit 216 is capable of performing data processing that achieves the actual function of the first integrated circuit 12. The memory control circuit 218 is capable of writing data processed by the data processing unit 216 into the data buffer 16 and reading data stored in the data buffer 16. The memory control circuit 218 is further capable of sending a read instruction signal S11 to the first integrated circuit 12 to instruct the first integrated circuit 12 to read data from the data buffer 16 and receiving a read completion signal S12 indicating completion of the reading of the data from the first integrated circuit 12. The data output controller 220 is capable of performing processing for allowing data processed by the data processing unit 216 or data read by the memory control circuit 218 from the data buffer 16 to be output to the outside.

The input interface 212, data processing unit 216, memory control circuit 218, and data output controller 220 are equivalent to the input interface 112, data processing unit 116, memory control circuit 118, and data output controller 120, respectively, contained in the first integrated circuit 12. That is, these components make up a so-called emulation circuit that imitates the functionality of the first integrated circuit 12. The provision of the emulation circuit in the circuit testing apparatus enables functional verification of the first integrated circuit 12 by simulation.

In a test, the data pattern reading and signal generating unit 202 of the circuit testing apparatus 20 reads, from an information processor or a signal generator, simulation pattern data for causing the internal emulation circuit to execute functions of the first integrated circuit 12.

The read simulation pattern data is provided from the data pattern reading and signal generating unit 202 to the input interface 212. Together with the data, a send data instruction is sent from the data pattern reading and signal generating unit 202 to the input interface 212.

In response to the send data instruction, the input interface 212 sends the simulation pattern data to the data processing unit 216. The data processing unit 216 performs predetermined processing on the simulation pattern data. The memory control circuit 218 writes the simulation pattern data processed by the data processing unit 216 into the data buffer 16. The data output controller 220 performs processing to allow data processed by the data processing unit 216 or data read by the memory control circuit 218 from the data buffer 16 to be output to the outside.

The test control signal generating unit 206 of the circuit testing apparatus 20 generates a test control signal S10 and sends the test control signal S10 to data output peripheral circuits of the first integrated circuit 12, namely the memory control circuit 118 and the data output controller 120. In response to the signal S10, the memory control circuit 118 and the data output controller 120 become active.

The memory control circuit 218 of the circuit testing apparatus 20 sends a read instruction signal S11 to the memory control circuit 118 of the first integrated circuit 12 to instruct the memory control circuit 118 to read data stored in the data buffer 16. In response to the signal S11, the memory control circuit 118 reads test pattern data from the data buffer 16. Upon completion of the data reading, the memory control circuit 118 sends a read completion signal S12 indicating the completion of the data reading to the memory control circuit 218 of the circuit testing apparatus 20.

The data output controller 120 of the first integrated circuit 12 outputs the test pattern data read through the memory control circuit 118 to the second integrated circuit 14 through the output interface 122. The second integrated circuit 14 operates to implement a predetermined function according to the test pattern data. Data resulting from the operation of the second integrated circuit 14 is output through the output interface 136. If the data matches the data expected to be output when the predetermined function is implemented by the second integrated circuit 14, it is determined that the first integrated circuit 12 functions properly and the connection between the first and second integrated circuits 12 and 14 is properly established. On the other hand, if the data does not match the expected data, it is determined that the first integrated circuit 12 does not properly function or there is a defect in the connection between the first and second integrated circuits 12 and 14.

In this way, the circuit testing apparatus of the second example embodiment incorporates a functional verification model and therefore is capable of performing evaluation of the interconnectivity between first and second integrated circuits 12 and 14 and, at the same time, functional verification of the first integrated circuit 12 by simulation. This enables generation of more flexible traffic patterns for evaluations such as evaluations in an environment closer to an actual traffic pattern and evaluations under high load (in burst transfer of short packets).

### Third Example Embodiment

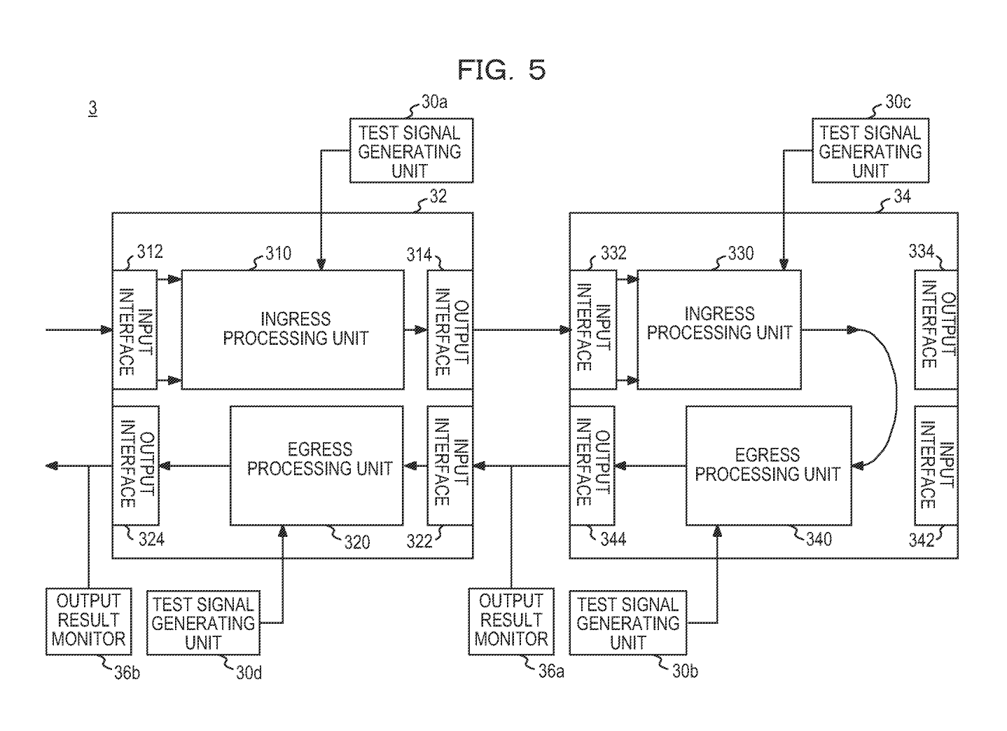

FIG. 5 illustrates a configuration of a circuit testing system according to a third example embodiment.

The circuit testing system 3 in FIG. 5 includes test signal generating units 30a to 30d, a first integrated circuit 32, a second integrated circuit 34, and output result monitors 36a and 36b.

Each of the test signal generating units 30a to 30d includes a circuit testing apparatus 10 used in the circuit testing system according to the first example embodiment illustrated in FIG. 2 or a circuit testing apparatus 20 according to the second example embodiment illustrated in FIG. 4, and external data buffers for the integrated circuits 32 and 34.

The first integrated circuit 32 may be an LSI used in a communication apparatus, for example, and includes an ingress processing unit 310 that performs ingress processing for data from a user to a network and an egress processing unit 320 that performs egress processing for data in the opposite direction. The first integrated circuit 32 further includes first and second input interfaces 312 and 322 and first and second output interfaces 314 and 324. Similarly, the second integrated circuit 34 includes an ingress processing unit 330 and an egress processing unit 340, first and second input interfaces 332 and 342, and first and second output interfaces 334 and 344. In the present example embodiment, each of the ingress processing unit 310 of the first integrated circuit 32 and the egress processing unit 340 of the second integrated circuit 34 has the same configuration as the first integrated circuit 12 illustrated in FIGS. 2 and 3. Each of the egress processing unit 320 of the first integrated circuit 32 and the ingress processing unit 330 of the second integrated circuit 34 has the same configuration as the second integrated circuit 14 illustrated in FIGS. 2 and 3.

The output result monitors 36a and 36b are information processors such as PCs for verifying the interconnectivity between the first integrated circuit 32 and the second integrated circuit 34 in the ingress processing path and egress processing path.

A data flow in ingress processing in actual use is as follows. Data is input in the first integrated circuit 32 through the first input interface 312, is subjected to predetermined processing by the ingress processing unit 310, and is output through the first output interface 314. The data output from the first integrated circuit 32 is received by the second integrated circuit 34 through the first input interface 332, is subjected to predetermined processing by the ingress processing unit 330, and is output through the first output interface 334. A data flow in egress processing in actual use is as follows. Data is input in the second integrated circuit 34 through the second input interface 342, is subjected to predetermined processing by the egress processing unit 340, and is then output through the second output interface 344. The data output from the second integrated circuit 34 is received by the first integrated circuit 32 through the second input interface 322, is subjected to predetermined processing by the egress processing unit 320, and is then output through the second output interface 324.

In a test, however, the ingress processing unit 310 of the first integrated circuit 32 acts as a signal generator that cooperates with the test signal generating unit 30a to generate a test signal for testing the ingress processing unit 330 of the second integrated circuit 34. The ingress processing unit 330 of the second integrated circuit 34 performs predetermined operation according to the test signal provided from the ingress processing unit 310 of the first integrated circuit 32. The result of the processing by the ingress processing unit 330 is routed back inside the second integrated circuit 34 and input in the egress processing unit 340, instead of being output to the outside through the first output interface 334. Such routing back of data is loopback functionality included in commercially available LSIs. Consequently, the result of processing by the ingress processing unit 330 is output from the second integrated circuit 34 through the egress processing unit 340 and the second output interface 344 and is observed by the output result monitor 36a provided at the output of the second integrated circuit 34. If the observed data matches the data expected to be output when the predetermined function is implemented by the ingress processing unit 330 of the second integrated circuit 34, it is determined that the connection between the first and second integrated circuits 32 and 34 in the ingress processing path is properly established. On the other hand, if the observed data is not the expected data, it is determined that there is a defect in the connection between the first and second integrated circuits 32 and 34 in the ingress processing path. In addition, if the result of processing by the ingress processing unit 330 is also processed by the egress processing unit 340 in the second integrated circuit 34, the functionality of the entire second integrated circuit 34 including the ingress processing unit 330 and the egress processing unit 340 can be verified.

The egress processing unit 340 of the second integrated circuit 34 acts as a signal generator that cooperates with the test signal generating unit 30b to generate a test signal for testing the egress processing unit 320 of the first integrated circuit 32. The egress processing unit 320 of the first integrated circuit 32 performs predetermined operation according to the test signal provided from the egress processing unit 340 of the second integrated circuit 34. The result of the processing by the egress processing unit 320 is output through the second output interface 324 and is observed by the output result monitor 36b provided at the output of the first integrated circuit 32. If the observed data matches the data expected to be output when the predetermined function is implemented by the egress processing unit 320 of the first integrated circuit 32, it is determined that the connection between the second and first integrated circuits 34 and 32 in the egress processing path is properly established. On the other hand, the observed data is not the expected data, it is determined that there is a defect in the connection between the second and first integrated circuits 34 and 32 in the egress processing path.

Another case will be considered where the ingress processing unit 330 of the second integrated circuit 34 has the same configuration as the first integrated circuit 12 illustrated in FIGS. 2 and 3 and an additional integrated circuit (not illustrated) is connected to the output of the second integrated circuit 34 through the first output interface 334. In this case, the ingress processing unit 330 acts as a signal generator that cooperates with the test signal generating unit 30c to generate a test signal for testing the ingress processing unit of the additional integrated circuit. Similarly, a case will be considered where the egress processing unit 320 of the first integrated circuit 32 has the same configuration as the first integrated circuit 12 illustrated in FIGS. 2 and 3 and an additional integrated circuit (not illustrated) is connected to the output of the first integrated circuit 32 through the second output interface 324. In this case, the egress processing unit 320 acts as a signal generator that cooperates with the test signal generating unit 30d to generate a test signal for testing the egress processing unit of the additional integrated circuit.

In this way, the integrated circuit under test also includes circuitry acting as a signal generator, that is, at least a memory control circuit 118 and the data output controller 120 and is therefore capable of testing another integrated circuit that acts as a signal generator.

Any of the circuit testing apparatuses and circuit testing systems disclosed in the example embodiments described above enables an actual device to readily generate data meaningful to integrated circuits under test. In the past, there have been LSIs having signal generating functionality of high-speed SerDes (Serializer/Deserializer) units. However, when such LSIs were used, the integrated circuits under test were able to generate only random data that is meaningless. That is, while verification could be made as to whether the outputting integrated circuit was able to properly receive data pattern generated by the inputting integrated circuit, additional man-hours and cost were required for performing interconnectivity verification testing that is implemented by the circuit testing apparatuses and systems disclosed herein. Therefore, the circuit testing apparatuses and systems disclosed herein are advantageous in that real interconnectivity verification testing can be performed while reducing the number of man-hours and cost involved in verification of the interconnectivity between integrated circuits.

The embodiment described above is a preferred embodiment. The present invention is not limited to this but various modifications can be made without departing from the spirit of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions has been described in detail, it should be understood that the various changes, substitutions, and alterations could be made hereto without departing from the spirit and scope of the invention.

What is claimed is:

1. A circuit testing apparatus testing interconnectivity between a first integrated circuit and a second integrated circuit, comprising:
a data writing unit, writing test pattern data causing the second integrated circuit to perform a predetermined operation into a data buffer of the first integrated circuit; and
a test control signal generating unit, generating a test control signal for causing the first integrated circuit to read the test pattern data from the data buffer and provide the test pattern data to the second integrated circuit.

2. The circuit testing apparatus according to claim 1, wherein the data writing unit comprises an emulation circuit imitating functionality of the first integrated circuit; and wherein
the emulation circuit performs predetermined processing on input simulation pattern data to generate the test pattern data.

3. The circuit testing apparatus according to claim 1, wherein the data writing unit sends a read instruction signal to the first integrated circuit to instruct the first integrated circuit to read data from the data buffer to the first integrated circuit and wherein the data writing circuit receives a read completion signal, indicating that the reading of the data has been completed, from the first integrated circuit.

4. A circuit testing system testing interconnectivity between an inputting integrated circuit and an outputting integrated circuit, comprising:
a first circuit testing apparatus having a first data writing unit which writes test pattern data for causing the outputting integrated circuit to perform a predetermined operation into a data buffer of the inputting integrated circuit and a first test control signal generating unit which generates a test control signal for causing the inputting integrated circuit to read the test pattern data from the data buffer and provide the test pattern data to the outputting integrated circuit, and testing interconnectivity between the inputting and outputting integrated circuits in an ingress data processing path going from the inputting integrated circuit to the outputting integrated circuit; or from the outputting integrated circuit to the inputting integrated circuit and
a second circuit testing apparatus having a second data writing unit which writes test pattern data for causing the outputting integrated circuit to perform a predetermined operation into a data buffer of the inputting integrated circuit and a second test control signal generating unit which generates a test control signal for causing the inputting integrated circuit to read the test pattern data from the data buffer and provide the test pattern data to the outputting integrated circuit, and testing interconnectivity between the outputting and inputting integrated circuits in an egress data processing path going from either the outputting integrated circuit to the inputting integrated circuit or from the inputting integrated circuit to the outputting integrated circuit.

5. The circuit testing system according to claim 4, wherein the outputting integrated circuit includes a loopback function and data obtained through the ingress data processing path is input in the egress data processing path within the outputting integrated circuit.

6. The circuit testing system according to claim 4, further comprising:
a first output result monitor which is provided at an output of the outputting integrated circuit in the egress data processing path and monitors whether connection between the inputting and outputting integrated circuits in the ingress data processing path is proper or not; and
a second output result monitor which is provided at an output of the inputting integrated circuit in the egress data processing path and monitors whether connection between the outputting and inputting integrated circuits in the egress data processing path is proper or not.

7. A circuit testing apparatus testing interconnectivity between a first integrated circuit and a second integrated circuit, comprising:
a data writing unit connected to a data buffer, wherein the data buffer is connected to a memory control circuit comprised in a first integrated circuit, and wherein the first integrated circuit is connected to a second integrated circuit.

8. The circuit testing apparatus according to claim 7, further comprising:
a test control signal generating circuit, wherein the test control signal generating circuit is connected to the data writing unit and the memory control circuit, and wherein the memory control unit is connected to the data writing unit.

9. The circuit testing apparatus according to claim 8, wherein the first integrated circuit and the second integrated circuit are identical circuits.

10. A circuit testing apparatus testing interconnectivity between a first integrated circuit and a second integrated circuit, comprising:
a memory control circuit connected to a data buffer and the first integrated circuit;
a data output controller connected to the memory control circuit;
a data processing unit connect to the memory control circuit and the data output controller;
an input interface connected to the data processing unit;
a data pattern reading and signal generating unit connected to the input interface; and
a test control signal generating unit connected to the data pattern reading and signal generating unit; wherein the test control signal generating unit is connected to the first integrated circuit, wherein the first integrated circuit is connected to the second integrated circuit.

11. The circuit testing apparatus testing interconnectivity between a first integrated circuit and a second integrated circuit according to claim 10, wherein the first integrated circuit and the second integrated circuit are identical circuits.

12. A circuit testing apparatus testing interconnectivity between a first integrated circuit and a second integrated circuit, comprising:
a first test signal generating unit connected to an ingress processing unit of the first integrated circuit;
a second test signal generating unit connected to an egress processing unit of the first integrated circuit;
a third test signal generating unit connected to an ingress processing unit of the second integrated circuit;
a fourth test signal generating unit connected to an egress processing unit of the second integrated circuit;
a first output monitor connected to an output interface of the first integrated circuit;
a second output monitor connected to an output interface of the second integrated circuit;
wherein
the first integrated circuit is connected to the second integrated circuit.

13. The circuit testing apparatus according to claim 12, wherein the first integrated circuit is identical to the second integrated circuit.
